(19) United States
(12) Patent Application Publication
(10) Pub. No.: US 2010/0279493 A1
(43) Pub. Date: Nov. 4, 2010

(54) DOPING OF SEMICONDUCTOR LAYER FOR IMPROVED EFFICIENCY OF SEMICONDUCTOR STRUCTURES

(76) Inventors: Kishore KAMATH, Fort Collins, CO (US); Alan R. DAVIES, Fort Collins, CO (US); Anders OLSSON, Bellvue, CO (US)

Correspondence Address: COOLEY LLP;ATTN: Patent Group, Suite 1100, 777 - 6th Street, NW, WASHINGTON, DC, 20001, US

(21) Appl. No.: 12/433,595

(22) Filed: Apr. 30, 2009

(51) Int. Cl. H01L 21/20; H01L 21/22

(52) U.S. Cl. 438/478; 438/542; 438/87; 257/E21.09; 257/E21.135

(57) ABSTRACT

A system and method for intentional doping, including variable doping, within a semiconductor structure for improved efficiency is described. One embodiment includes a method for forming a semiconductor structure, the method comprising forming a first semiconductor layer, wherein the first semiconductor layer comprises a first semiconductor material, and forming a second semiconductor layer on the first semiconductor layer, wherein the second semiconductor layer comprises a second semiconductor material, wherein the second semiconductor material is an oppositely-typed semiconductor material from the first semiconductor material, and wherein the second semiconductor layer comprises a first region adjacent to the first semiconductor layer, wherein the first region comprises second semiconductor material, and a second region adjacent to the first region, wherein the second region comprises intentionally doped second semiconductor material to increase a built-in potential of the semiconductor structure.

### RELATED APPLICATIONS

The present application is related to commonly owned and assigned application Attorney Docket No. AVAS-003/00US, entitled Doping of Semiconductor Layer for Improved Efficiency of Semiconductor Structures, filed Apr. 30, 2009, which is incorporated herein by reference.

### FIELD OF THE INVENTION

The present invention relates to band structure engineering of semiconductor structures. In particular, but not by way of limitation, the present invention relates to systems and methods for doping and variable doping within a semiconductor structure for improved efficiency, such as in use with thin film solar cells.

### BACKGROUND OF THE INVENTION

A photovoltaic cell is a structure that is capable of converting light into electricity by the photovoltaic effect. In application, photovoltaic cells can be interconnected as part of a photovoltaic module that can be used in various devices—from small indoor pocket calculators to large industrial solar arrays. The ability of a photovoltaic cell to convert sunlight into electricity makes photovoltaic modules a potential major energy source. In addition, due the ‘renewable’ nature of sunlight, the use of photovoltaic modules as an energy source has significant potential environmental benefits. However, in order to achieve these benefits, photovoltaic modules must be cost effective energy sources. The cost effectiveness of photovoltaic modules depends, in part, on the efficiency of the photovoltaic module.

The basic structure of a typical photovoltaic module includes 1) a front substrate, such as glass or plastic; 2) a front electrical contact, such as an electrical contact grid or a coating of a transparent conductive oxide (TCO); 3) a semiconductor structure, such as a homostructure or heterostructure; 4) a back electrical contact; and 5) a back substrate, such as a glass plate or a plastic plate. In operation, sunlight passes through the front substrate, past the front electrical contact, and is absorbed by the semiconductor structure. During this absorption, photons from the sunlight are absorbed by electrons in the semiconductor structure. If the energy of a photon is sufficient (i.e., if the energy of the photon is equal to or greater than the band gap energy of the material in which the photon is absorbed), the electron is knocked loose creating an electron and a hole, sometimes referred to as an electron-hole pair. The electron and the hole are also referred to as charge carriers. Once knocked loose, the electron and the hole are able to flow in opposite directions through the semiconductor structure. While the direction of flow depends on the characteristics of the semiconductor structure, the electron and hole will flow in opposite directions towards either the front electrical contact or the back electrical contact.

The efficiency of a photovoltaic module is related to various factors including the voltage potential of the photovoltaic module and the Quantum Efficiency (QE) of the photovoltaic module. Both the voltage potential and the QE are based, at least in part, on properties of the semiconductor structure.

The voltage potential of a photovoltaic module is related to multiple factors, including, but not limited to, the band gap of the materials comprising the semiconductor structure, the level of doping of the materials comprising the semiconductor structure, and any Schottky barrier between the semiconductor structure and an adjacent electrical contact.

The QE of a photovoltaic module is related to both the External Quantum Efficiency (EQE) and the Internal Quantum Efficiency (IQE) of the photovoltaic module. Of particular relevance to the design of the semiconductor structure is the IQE. The Internal Quantum Efficiency (IQE) is the ratio of the number of charge carriers (electrons and holes) collected by the photovoltaic module to the number of charge carriers (electrons and holes) freed. If every electron-hole pair freed by a photon is collected by the photovoltaic module, the IQE would be equal to one. However, in practice the IQE is reduced due to the effects of recombination within the semiconductor structure.

Although present devices are functional, they do not sufficiently address efficiency factors. Accordingly, a system and method are needed to address the shortfalls of the present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention can provide a system and method for doping and variable doping within a semiconductor structure for improved efficiency. In one exemplary embodiment, the present invention can include a semiconductor structure, the semiconductor structure comprising a first semiconductor layer comprising a first semiconductor material, and a second semiconductor layer comprising a second semiconductor material, wherein the second semiconductor material is an oppositely-typed semiconductor material from the first semiconductor material, and wherein the second semiconductor layer comprises a first region adjacent to the first semiconductor layer, wherein the first region comprises low-doped second semiconductor material, and a second region adjacent to the first region, wherein the second region comprises highly-doped second semiconductor material to increase a built-in potential of the semiconductor structure.

In another exemplary embodiment, the present invention can include a semiconductor structure comprising a n-type semiconductor layer, a p(⁻)-type semiconductor layer, and a p(⁺)-type semiconductor layer, wherein the p(⁻)-type semiconductor layer is positioned between the p(⁺)-type semiconductor layer and the n-type semiconductor layer.

In another exemplary embodiment, the present invention can include a method for forming a semiconductor structure, the method comprising forming a first semiconductor layer, wherein the first semiconductor layer comprises a first semiconductor material, and forming a second semiconductor layer on the first semiconductor layer, wherein the second semiconductor layer comprises a second semiconductor material, wherein the second semiconductor material is an oppositely-typed semiconductor material from the first semiconductor material, and wherein the second semiconductor layer comprises a first region adjacent to the first semiconductor layer, wherein the first region comprises second semiconductor material, and a second region adjacent to the first region, wherein the second region comprises intentionally doped second semiconductor material to increase a built-in potential of the semiconductor structure.

In another exemplary embodiment, the present invention can include a method for forming a semiconductor structure, the method comprising forming a first layer, wherein the first layer comprises a first semiconductor material, forming a second layer on the first layer, wherein the second layer comprises low-doped second semiconductor material, wherein the second semiconductor material and the first semiconductor material are oppositely-typed semiconductor materials, and forming a third layer on the second layer, wherein the third layer comprises high-doped second semiconductor material.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1—Exemplary band diagram of a typical semiconductor structure.

FIG. 2—Exemplary band diagram of a semiconductor structure showing band diagram for ohmic contact and differences between the band diagram for low-doped and high-doped material.

FIG. 3—Band diagram for an exemplary semiconductor structure with variable step-doping in accordance with an embodiment of the present invention.

FIG. 4—Band diagram of n(⁺)-p(⁻) CdS/CdTe semiconductor structure where Fermi-level pinning at the CdTe surface leads to a built in barrier (Schottky barrier) for hole transport resulting in loss of built-in voltage potential.

FIG. 5—Band diagram of n(⁺)-p(⁻) CdS/CdTe semiconductor structure where heavy doping close to CdTe surface reduces the effect of Fermi-level pinning by forming a tunneling junction, giving a good ohmic contact.

FIG. 6—Band diagram for a high level p-doping CdTe semiconductor structure (n(⁺)-p(⁺) structure) showing reduced gap between valence band and Fermi-level and increased long minority carrier diffusion lengths.

FIG. 7—Band diagram for an exemplary semiconductor structure with single-step-doping of CdTe to form a n(⁺)-p(⁻)-p(⁺) structure in accordance with an embodiment of the present invention.

FIG. 8—Band diagram for an exemplary semiconductor structure with graded-doping of CdTe to form a n(⁺)-p(⁻)-p(⁺) structure in accordance with an embodiment of the present invention.

FIG. 9—Band diagram for an exemplary semiconductor structure with modulation doping to form a variable doping structure in accordance with an embodiment of the present invention.

FIG. 10—Band diagram for an exemplary semiconductor structure with delta-doping to form a variable doping structure in accordance with an embodiment of the present invention.

### DETAILED DESCRIPTION

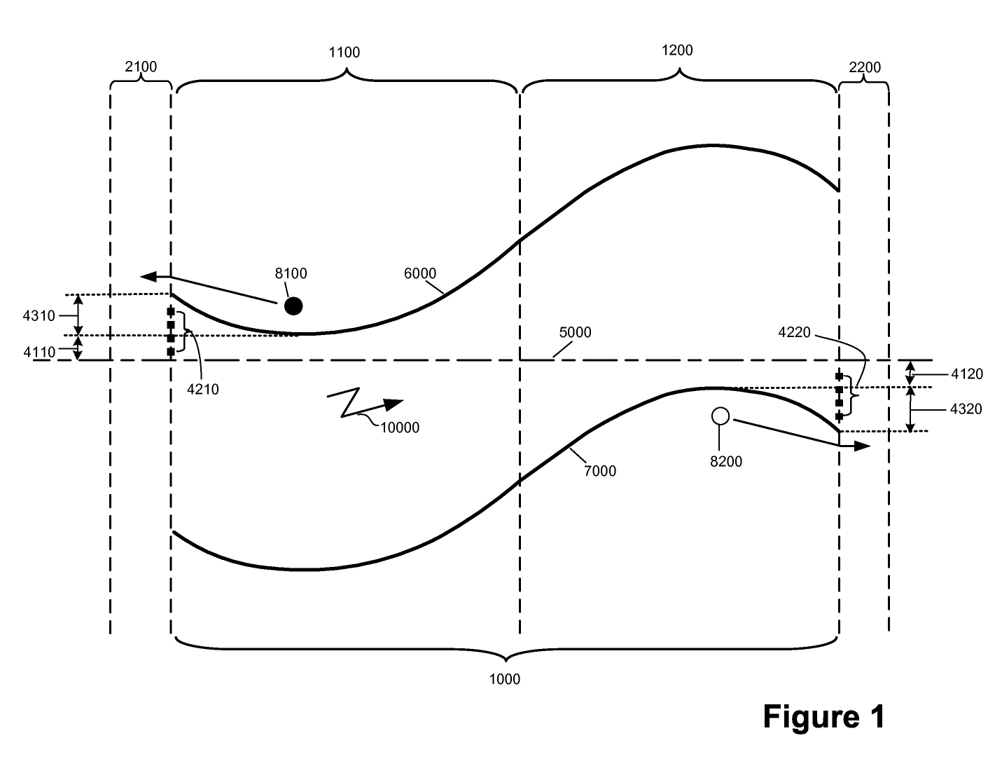

Referring now to the drawings, where like or similar elements are designated with identical reference numerals throughout the several views, and referring in particular to FIG. 1, it illustrates an exemplary band diagram for a semiconductor structure 1000 positioned between a front electrical contact 2100 and a back electrical contact 2200. In general, a semiconductor structure 1000 refers to the region between the front electrical contact 2100 and back electrical contact 2200 comprised of at least two semiconductor materials of different type (n-type or p-type semiconductor material). The semiconductor structure 1000 could be a homostructure or heterostructure. The semiconductor structure 1000 shown in FIG. 1 is comprised of two layers of semiconductor material (1100, 1200). In this example, the first layer 1100 is comprised of a n-type semiconductor material and the second layer 1200 is comprised of a p-type semiconductor material. For purposes of discussion, the semiconductor structure 1000 in FIG. 1 can be assumed to be a n(⁻)-p(⁻)-homostructure with an equal band gap between the first layer 1100 and the second layer 1200. It should be recognized that the first layer 1100 and the second layer 1200 may be comprised of multiple layers of semiconductor material. Light 10000 is shown traveling into the semiconductor structure 1000 for absorption. For example, the first layer 1100 and the second layer 1200 may comprise multiple thin films.

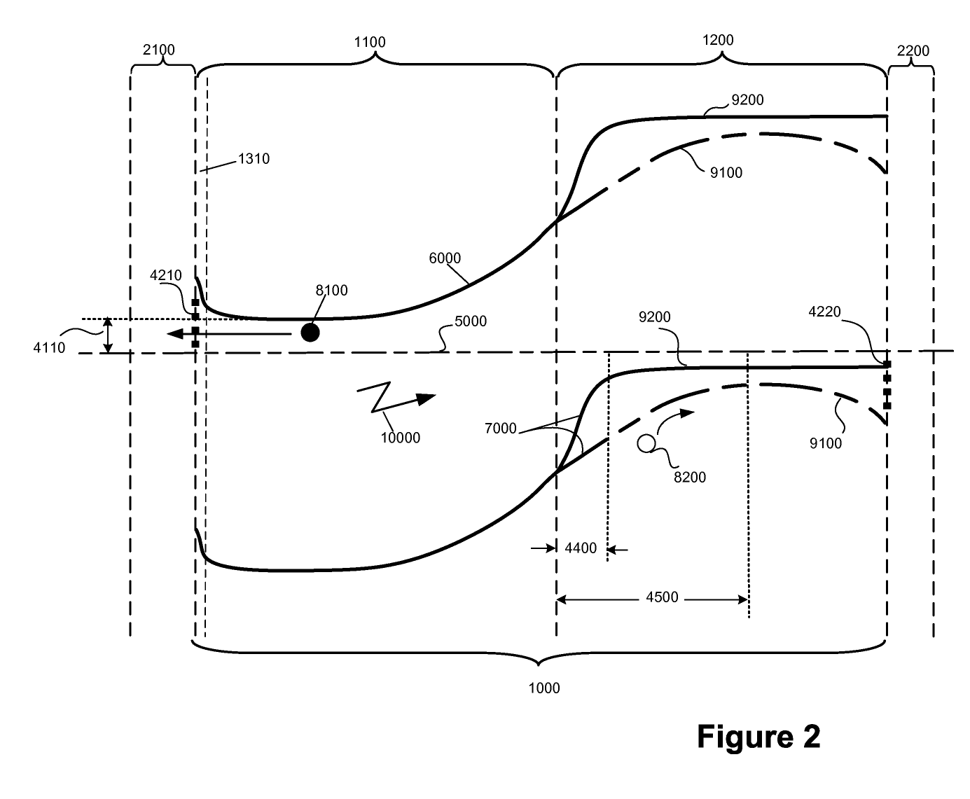

Two of the sources of inefficiency in the semiconductor structure 1000 in FIG. 1 are (a) the loss of voltage potential due to the level of doping, shown by 4110 and 4120, and (b) the loss of voltage potential due to band bending caused by a Schottky barrier (4210, 4220). The loss of voltage due to the Schottky barrier (4210, 4220) is shown by 4310 and 4320. It will be recognized by those of skill in the art that the level of doping in each layer (1100, 1200) affects the amount of band bending in the semiconductor structure 1000 and, thus, the built-in voltage potential. For example, in a n(⁻)-type semiconductor, such as in the first layer 1100 in FIG. 1, when the doping level is increased the gap 4110 between Fermi-level 5000 and conduction band 6000 decreases, resulting in greater band bending and higher built-in voltage potential. Similarly, in a p(⁻)-type semiconductor, such as in the second layer 1200, when the level of doping is increased the gap 4120 between the Fermi-level 5000 and valence band 7000 decreases, resulting in greater band bending and higher voltage potential. This is shown in FIG. 2, as discussed further below. Because both the first layer 1100 and the second layer 1200 in FIG. 1 are low-doped semiconductor layers, which can include, an intrinsic semiconductor, unintentionally doped semiconductor material, and/or an extrinsic semiconductor, there is lost voltage potential, and thus inefficiency, due to the gaps (4110, 4120) between the conduction band 6000 and Fermi-level 5000 in the first layer 1100 (the n-type semiconductor layer) and valence band 7000 and Fermi-level 5000 in the second layer 1200 (the p-type semiconductor layer).

A Schottky barrier 4200 is another potential cause for inefficiency in a semiconductor structure 1000. A high density of defect states at the surfaces of a semiconductor structure 1000 results in Fermi-level pinning causing band bending. As indicated in FIG. 1 this band bending forces a potential barrier 4200 for the charge carriers (electron 8100, hole 8200). This potential barrier, usually referred to as the Schottky barrier 4200, increases the series resistance of a photovoltaic cell. This increase in series resistance effectively reduces the voltage and thereby increases the inefficiency of the photovoltaic cell.

FIG. 2 depicts a semiconductor structure 1000 similar to FIG. 1. In FIG. 2 an ohmic contact 1310 has been formed in the first layer 1100 by heavily doping the surface of the first layer 1100 which is adjacent to the front electrical contact 2100. In addition, in the second layer 1200 it shows two band diagrams (9100, 9200). The first band diagram is a p(⁻)-band diagram 9100 representative of the second layer 1200 being a p(⁻)-type semiconductor as discussed in FIG. 1. The second band diagram is a p(⁺)-band diagram 9200 representative of the second layer 1200 being a p(⁺)-type semiconductor.

Referring first to the addition of the ohmic contact 1310 in FIG. 2, the ohmic contact 1310 is created by heavy doping near the surface which allows for carrier tunneling. This carrier tunneling helps eliminate at least a portion of the band bending, and loss of voltage potential, due to the Schottky barrier 4210. However, the ohmic contact 1310 in the first layer 1100 does not reduce the gap 4110 between the conduction band 6000 and Fermi-level 5000. Instead, the loss of voltage potential due to that gap 4110 is still a source of inefficiency in the photovoltaic cell.

The semiconductor material in the second layer 1200 in FIG. 2 has been heavily doped in order to create a p(⁺)-type semiconductor layer. As shown by the p(⁺)-band diagram 9200, this heavy doping can both reduce the gap between valence band and Fermi-level resulting in greater voltage potential, and minimize the losses due to surface states (i.e., help eliminate the band bending and loss of voltage potential due to the Schottky barrier 4220). It should, however, be noted that heavy doping drastically reduces the depletion width in the second layer 1200 requiring charge carriers (8100, 8200) to be transported by diffusion. The depletion region in a semiconductor is a region or zone in which the charge transport is by drift mechanism—or forced by an electric field. The depletion width is the width of the depletion region in a semiconductor. The depletion width for the p(⁺)-type semiconductor 4400 is smaller than the depletion width for the p(⁻)-type semiconductor 4500 of the same material. The difference in depletion width between the p(⁺)-type semiconductor and p(⁻)-type semiconductor is shown in FIG. 2. A reduced depletion width puts a burden of requiring longer diffusion, leading to increased recombination and a lower Internal Quantum Efficiency (IQE). This is because although the same number of charge carriers (8100, 8200) are created, the charge carriers (8100, 8200) are more likely to recombine during diffusion than during depletion.

One new design approach is to intentionally dope one of, or both, the semiconductor layers (1100, 1200) to a level that allows for an increase in the built-in potential of the semiconductor structure 1000 without substantially reducing depletion width. This moderate intentional doping is a compromise between the positive effects of high-doping (e.g., increased built-in voltage potential) and the negative effects of high-doping (e.g., decreased depletion width).

Another approach is to use variable doping in a semiconductor layer, or semiconductor layers, in a semiconductor structure 1000. This variable doping can increase efficiency by reducing the gap between valence/conduction band and Fermi-level (increasing built-in voltage potential), minimize the losses due to surface states (preventing loss of voltage potential), and help maintain depletion width (reducing recombination and increasing IQE). As mentioned above, a semiconductor structure 1000 is comprised of at least two semiconductors of different type (n-type or p-type). For example, a homostructure is a semiconductor structure 1000 wherein the structure is comprised of two oppositely typed semiconductors with equal band gaps. A heterostructure is a semiconductor structure 1000 comprised of two dissimilar semiconductors materials with unequal band gaps. More complex semiconductor structures with more than two semiconductor materials are also known to those of skill in the art and could be used with the concepts of the present application. Consistent with the present invention, the doping profile of a semiconductor layer, or semiconductor layers, in the semiconductor structure 1000 can be tailored to achieve improvement in voltage potential while still maintaining adequate depletion width.

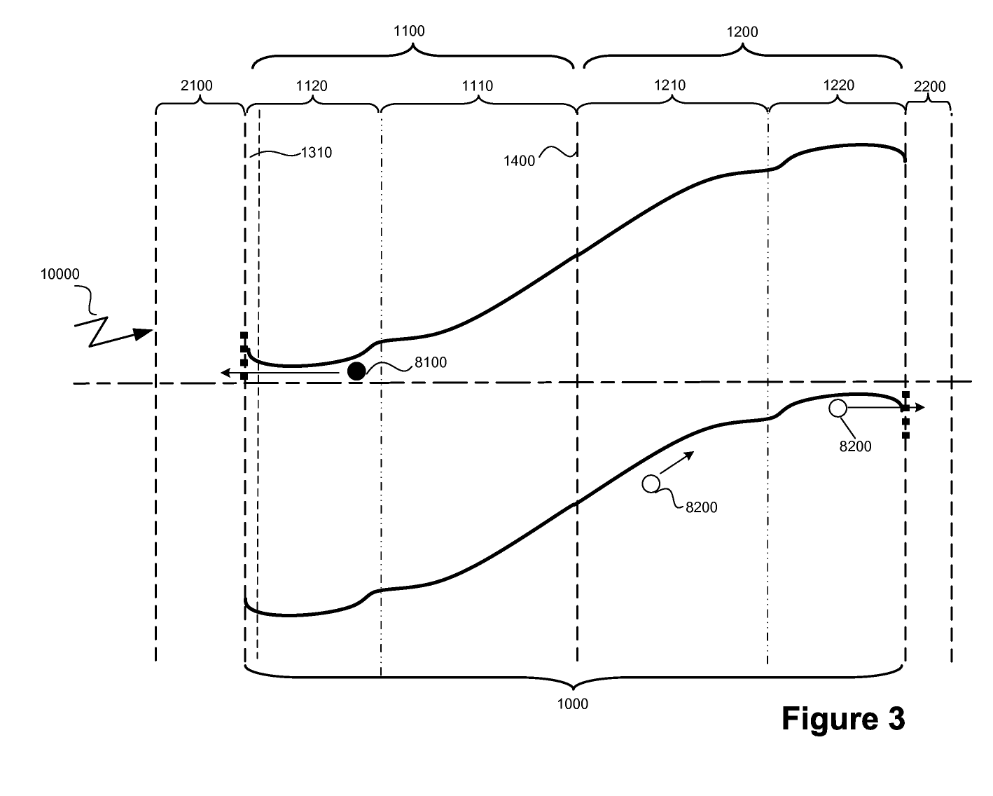

Referring now to FIG. 3, it shows an embodiment of the present invention using step-doping. Step-doping refers to variable regions of doping within a semiconductor material layer. FIG. 3 depicts two layers (1100, 1200) of different semiconductor materials. One or both layers (1100, 1200) may be comprised of two regions of variable doping. For example, the first layer 1100 is comprised of two regions (e.g., layers, bulk layers, films) (1110, 1120) of the same semiconductor material but with different doping levels in each region. The first layer 1100 is an n-type semiconductor material where the semiconductor layer comprises a n(⁻)-type region 1110 near the p-n junction 1400 and n(⁺)-type region 1120 near the front electrical contact 2100. Similarly, step-doping could be used in the second layer 1200 where the semiconductor material comprises a p(⁻)-type region 1210 near the p-n junction 1400 and p(⁺)-type region 1220 near the back electrical contact 2200.

FIG. 3 shows step-doping in both semiconductor layers (1100, 1200). Embodiments of the present invention can include variable doping in one or multiple semiconductors in a semiconductor structure. Moreover, while FIG. 3 depicts step-doping, there are other ways one can achieve minimum doping near the junction between semiconductor materials (e.g., the p-n junction 1400) and maximum doping near the outer surface or contact with a front 2100 or back electrical contact 2200. For example, some of the other ways to achieve this variable doping include graded doping, modulation doping, and delta doping. Additional variable doping techniques will be realized by those skilled in the art consistent with the present invention.

In addition to recognizing that the doping profile across a semiconductor layer (1100, 1200) can take many forms consistent with the present invention, the doping profile across each region (1110, 1120, 1210, 1220) within a semiconductor layer can also take many forms. For example, in the second layer 1200 in FIG. 3, the doping profile across each region (1210, 1220) can be uniform and consistent across the region or can vary across the region. In this respect, a reference to a region as low-doped or high-doped is in reference to the doping density across the entire region. For example, in the second semiconductor layer 1200, the second region 1220 may comprise low-doped semiconductor material, but the amount of high-doped semiconductor material could be sufficient so that the region 1220 is viewed as highly-doped.

The width of the semiconductor layers (1100, 1200), and the regions (1110, 1120, 1210, 1220) within the semiconductor layers may vary based on design considerations. In general, the width of the regions (1110, 1210) adjacent to the p-n junction 1400 should be sufficient to maintain depletion width in the absorption region. And the width of the high-density regions (1120, 1220) should be sufficient in order to increase the built-in potential of the semiconductor structure 1000. For example, consider the second semiconductor layer 1200 in FIG. 3. The width of the second region 1220, may be increased or decreased depending on the doping density. If the second region 1220 is not sufficiently wide, it will be insufficient to increase the built-in potential of the semiconductor structure 1000.

In one embodiment of the present invention, the doping profile of the second semiconductor layer 1200 could gradually increase from a low doping density near the p-n junction 1400 to a high doping density near the surface. This gradual increase could be uniform or could vary across the width of the second semiconductor layer 1200. In one embodiment, the increase in doping density could increase exponentially in relation to the distance from the p-n junction 1400. Those of skill in the art will understand that there are numerous doping profiles that could be used consistent with the present invention.

As discussed above, the appropriate width of the first and second layers (1100, 1200) and the first and second regions (1110, 1120, 1210, 1220) within those layers can change based on design parameters. The level of doping in these regions/layers will also vary depending on design parameters. Generally, a low doping density can be used to refer to anything under 1E15 per cubic centimeter and high density as anything over 1E17. But the doping density of a specific region or layer may have to be lower or higher depending on the thickness of the region and the doping density of any surrounding regions. In one embodiment, a moderate doping density between 1E15 and 1E17 could be used throughout both regions of a given layer (1100, 1200). Those of skill in the art will realize that the doping density can be modified, changed or adjusted consistent with the present invention.

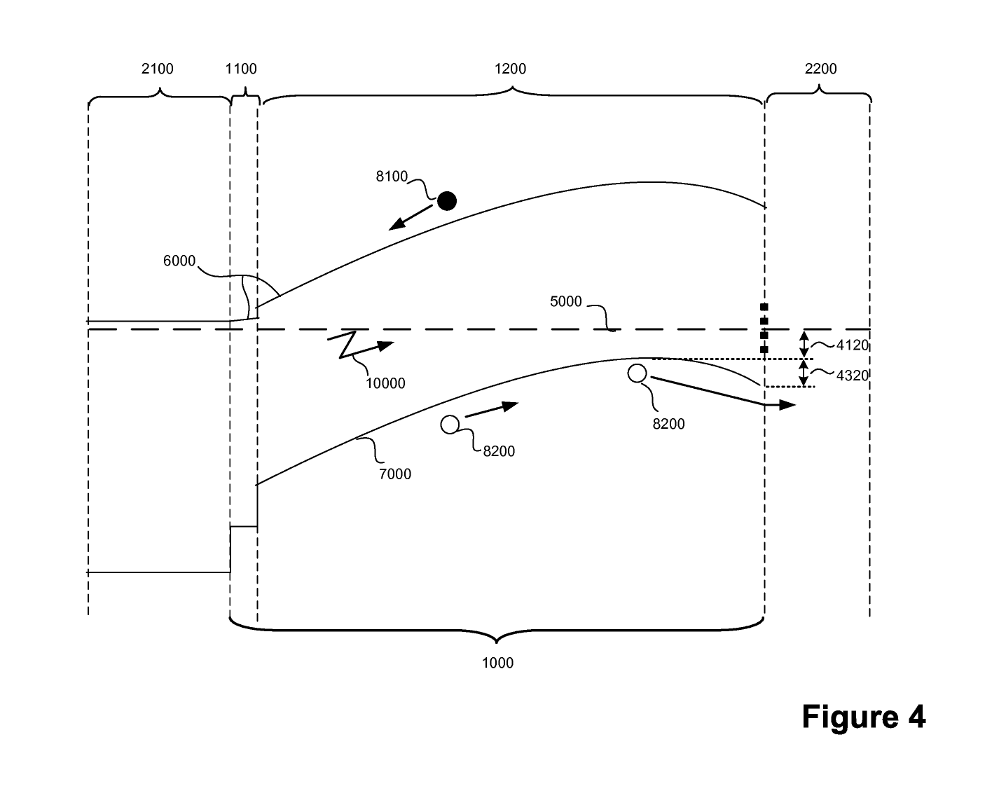

Those of skill in the art will understand that the present invention can be used in multiple different types of semiconductor structures. By way of example, in FIG. 4 there is a realistic band diagram for a n(⁺)-p(⁻)-CdS/CdTe heterostructure 1000. As shown in FIG. 4, the CdS/CdTE semiconductor structure 1000 is comprised of a n-type-CdS layer 1100 and p-type-CdTe layer 1200. Due to the insufficient doping in the p-type-CdTe layer 1200, there is both Schottky barrier 4220 band bending (resulting in voltage potential loss 4320) and a gap between valence band 7000 and Fermi-level 5000 (representing lost, or unachieved, voltage potential).

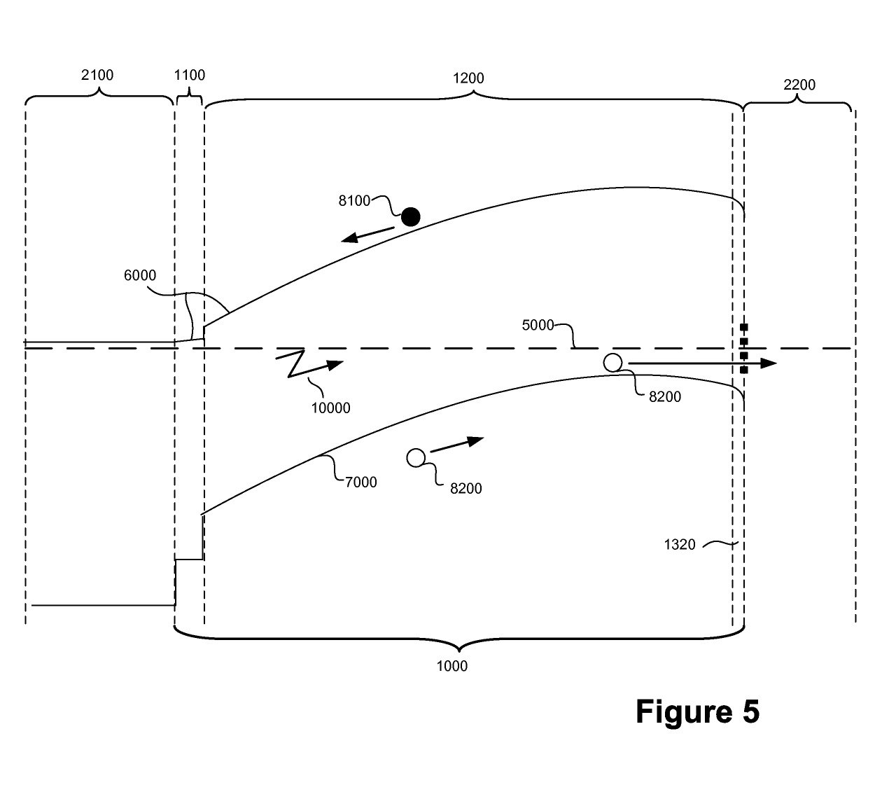

FIG. 5 shows one general way to improve the efficiency of the CdS/CdTe heterostructure in FIG. 4. In FIG. 5 copper doping (as Cd substitution impurity) has been added to get ohmic contact 1320 at the p-type-CdTE surface. However, copper doping has a significant drawback. Copper can easily diffuse through CdTe, particularly if it is incorporated as interstitial defect. This significantly affects the reliability of the photovoltaic module. Therefore, copper doping has to be controlled accurately to provide high level Cd-substitution doping near the surface and minimize the diffusion into CdTe bulk layer.

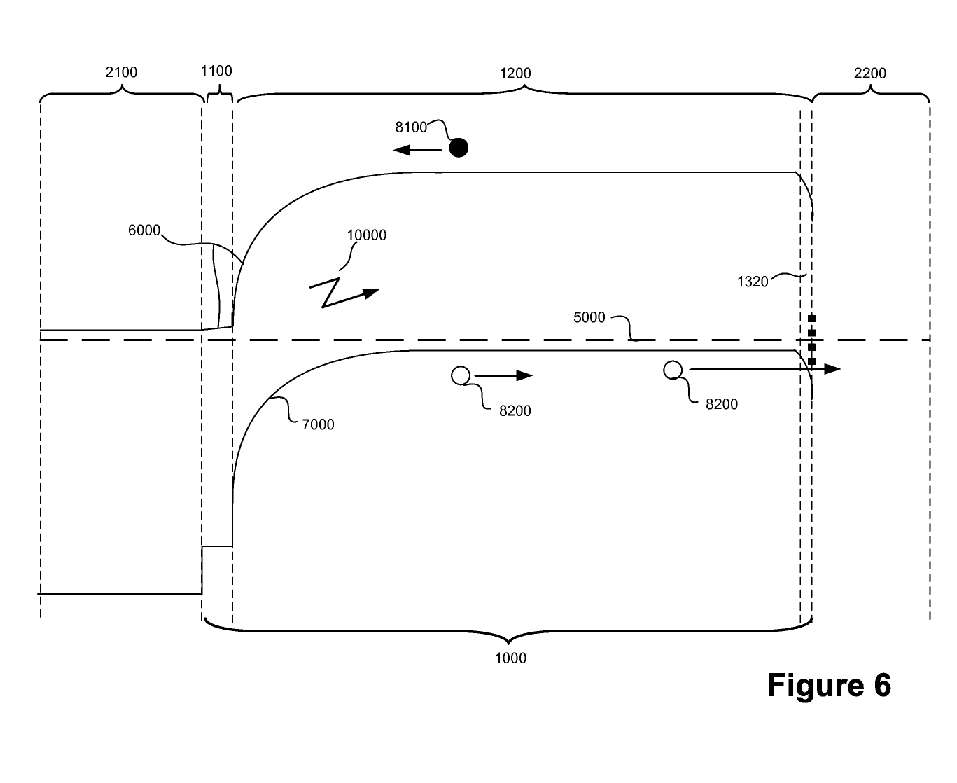

A photovoltaic cell made from the structure described in FIG. 5 will typically deliver open circuit voltages of around 800 mV, with values reported as high as approximately 850 mV. A significant improvement in voltage should be achievable for a material with a band gap of 1.5 eV. One of the reasons for inefficiency is the gap (4120+4320) between valence band 7000 and the Fermi-level 5000 due to a combination of low doping and band bending caused by surface states (Schottky barrier 4220). As discussed above, increasing the p-type doping of the CdTe can help in addressing both of these issues. As shown in FIG. 6, high level p-type doping (p(⁺)-type doping) brings Fermi-level 5000 close to the valence band 7000 and also minimizes the loss 4320 due to the effect of surface states. Once again, however, this heavy p(⁺)-type doping drastically reduces the depletion width in the CdTe requiring charge carriers (hole 8200) to be transported by diffusion through a significant portion of the CdTe. This leads to higher recombination rates and a lower IQE.

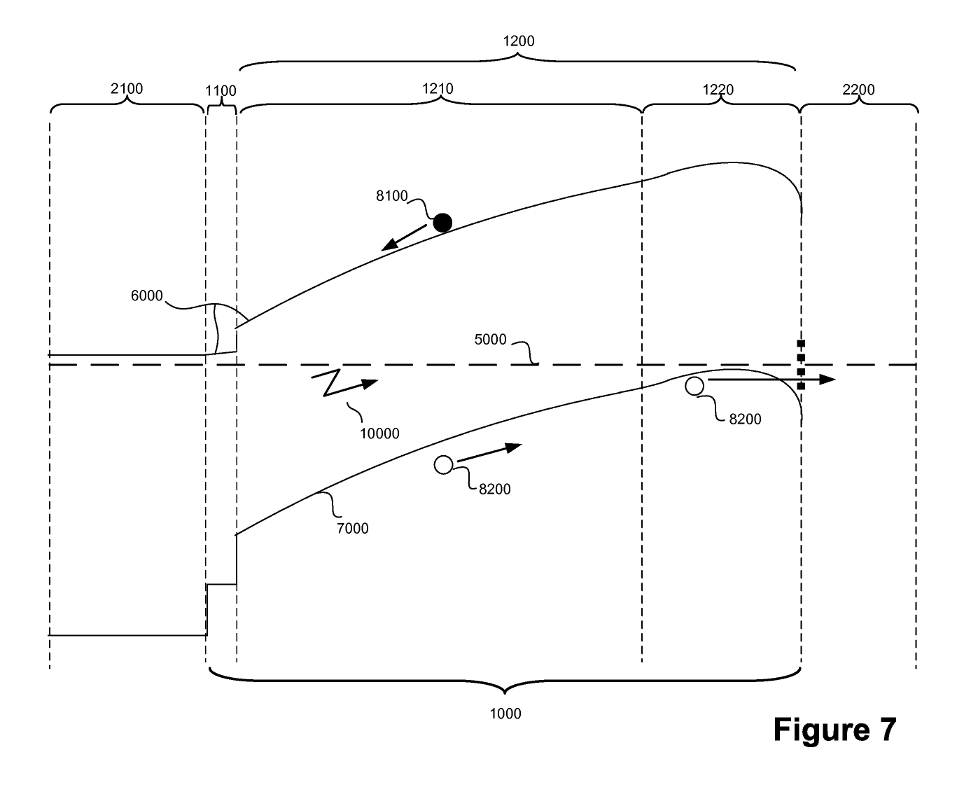

FIGS. 7-10 depict alternate variable doping design approaches for the CdTe layer 1200 consistent with the present invention. Using variable doping, the doping profile can be tailored to achieve improvement in voltage while still maintaining adequate depletion width in the absorption region. Referring first to FIG. 7, it shows one embodiment consistent with the present invention using step-doping. In FIG. 7 CdTe near the p-n junction 1400 is low-doped p(⁻)-CdTe and is stepped up to high doped CdTe (p(⁺)-CdTe) near the contact 2200, to give an n(⁺)-p(⁻)-p(⁺) doping profile. In this embodiment, the CdTe layer 1200 comprises two regions (1210, 1220). The first region is a p(⁻)-CdTe region 1210 comprising low-doped CdTe. The second region is a p(⁺)-CdTe region 1220 comprising highly-doped CdTe. In one embodiment, the second region 1220 may be sufficiently doped near the surface to form an ohmic contact 1320 with an electrical contact 2200. In some embodiments, the ohmic contact 1320 may be formed by degenerate level doping near the surface using the same dopant used to dope the second region 1220. In other embodiments, a different dopant may be used to form the ohmic contact 1320. For example, Cu is a common dopant used to create an ohmic contact for CdTe. However, it may be preferred to use a different dopant to create the p(⁺)-CdTe region 1220 because of the potential problems associated with Cu.

The width of the CdS layer 1100 and CdTe layer 1200, and the regions (1110, 1120, 1210, 1220) within those layers may vary based on design considerations. For example, the CdS layer 1100 could 100-400 nanometers thick with a CdTe layer 1200 between 2-4 microns thick. Within the CdTe layer 1200, the low-doped region 1210 could comprise 70-85% of the total thickness, with the high-doped region comprising the remaining 15-30%.

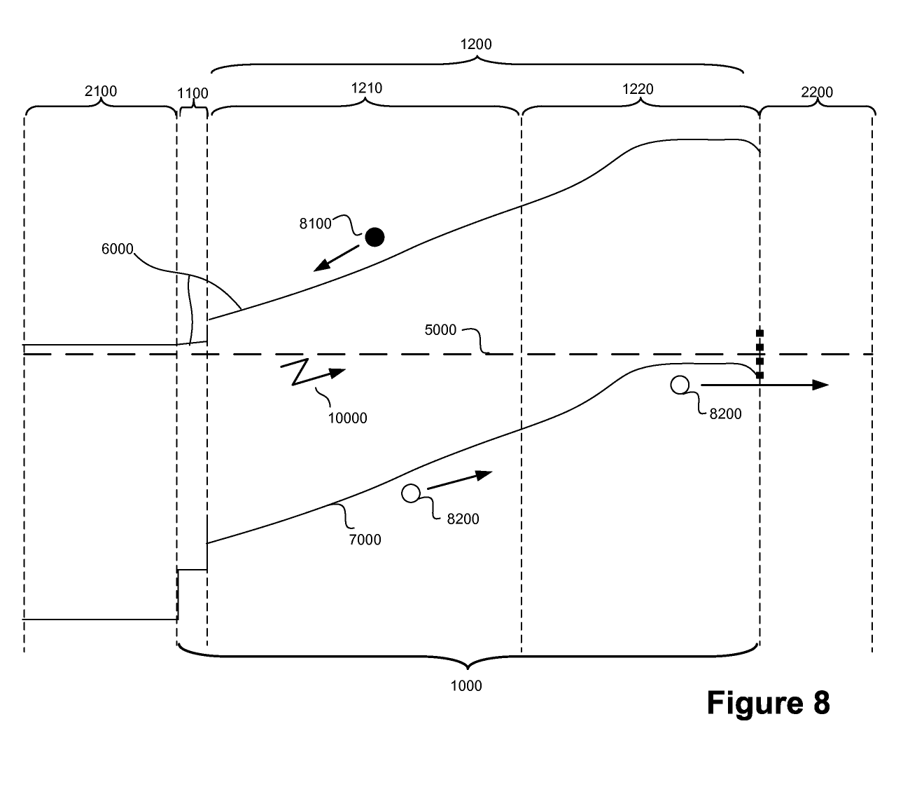

Step-doping is not the only method of achieving the objective of minimum doping near the p-n junction 1400 and maximum doping near the surface. FIG. 8 shows an embodiment of the present invention using graded doping. As shown in FIG. 8, p-type doping in the CdTe layer 1200 is increased from a low value (for example, around 1E14) near the CdS/CdTe junction 1400 to a high value (for example, around 1E19) close to where the CdTe surface meets the back contact 2200. In fact, CdTe near the junction 1400 can even be intrinsic, if possible. Numerous method may be used to achieve the graded doping. In one embodiment, graded doping can be achieved through diffusion of dopants from the CdTe layer's 1200 surface. In another embodiment, the CdTe layer 1200 may comprise thin CdTE films of increasing doping density. In some graded doping embodiments, the first region 1210 and second region 1220 could have substantially the same doping level where the two regions meet. In other embodiments, graded doping could be combined with step-doping to create a density jump between regions (1210, 1220), while still having a graded doping profile within one or both regions (1210, 1220). Those of skill in the art will be aware of many modifications, combinations and alternatives consistent with the present invention.

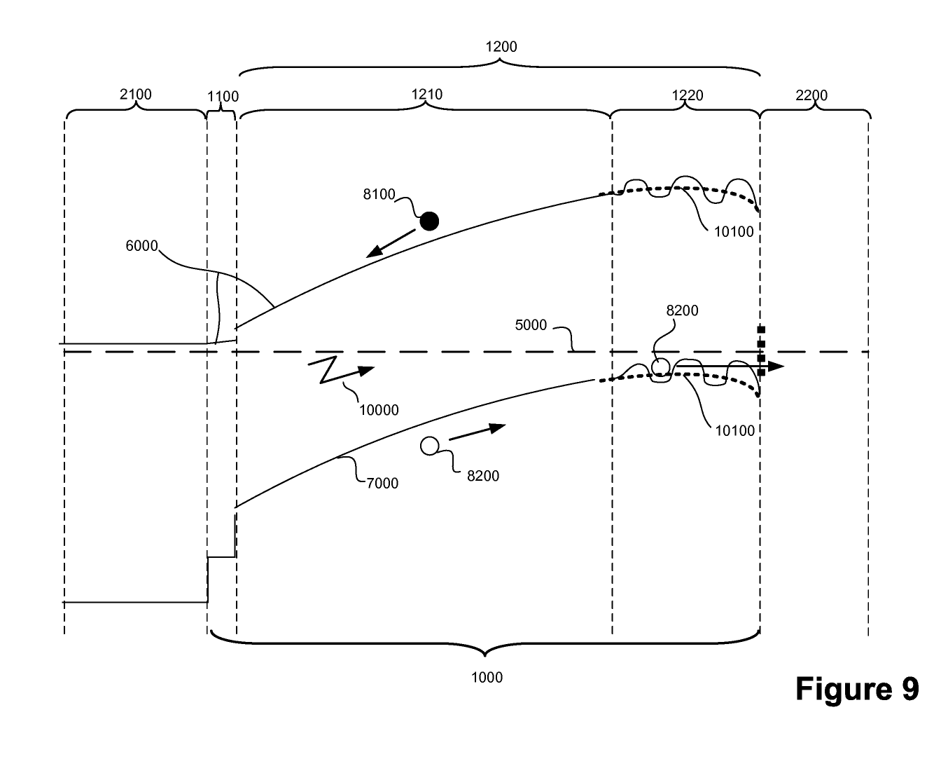

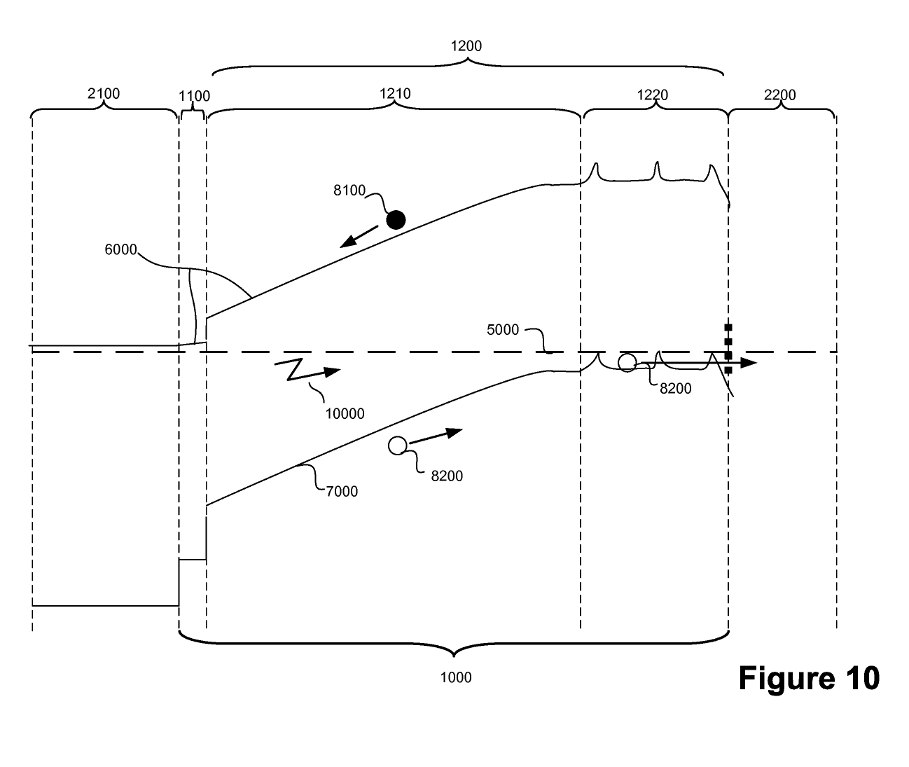

FIG. 9 shows an embodiment using modulation doping. In FIG. 9 alternate thin sections of high and low level doping are used to give an effective doping profile 10100 that can be tailored to achieve any desired profile. This has the advantage that any complex doping profile can be achieved using just two source materials. A special case of modulation doping is shown in FIG. 10. In FIG. 10 thin layers of very heavily doped material are inserted within the CdTe layer 1200 to effectively move valence band 7000 edge closer to Fermi-level 5000 without significantly degrading the properties of the CdTe material.

The ohmic contact at the back electrical contact 2200 is not shown in FIGS. 7-10. However, it is noted that in many embodiments the second region 1220 will include an ohmic contact 1320. This ohmic contact could be formed by achieving sufficient levels of doping in the second region 1220. As noted previously, this level of doping could be achieved using the same dopant used to dope the second region 1220, or a different dopant. Those of skill in the art will be aware of many ways to form the ohmic contact.

Numerous different dopants could be used with the CdTe consistent with the present invention. For example, elements from Group V of the periodic table, such as N, P, As, Sb and Bi, can provide acceptor doping when substituting Te site in the lattice to achieve p-type (acceptor) doping. Similarly, Group IB elements (Cu, Ag, Au) and Group IA elements (e.g., Li, Na, K) can also give acceptor doping when substituting Cd site in the lattice. In addition, it is possible to have acceptor doping through native defects and the formation of a complex. For example, Cd vacancy will form two acceptor levels in the bandgap while it also gives an acceptor level when forming a complex with Chlorine.

Nothing in the present discussion should be read to limit the present invention to CdS/CdTe semiconductor structures. Band structure engineering consistent with the present invention can be used to improve the efficiency of any semiconductor structure. The present invention could be used with other material systems including, but not limited to, silicon, CIS, CIGS, GaAs and InP based semiconductor structures.

In conclusion, the present invention provides, among other things, a system and method for variable doping within a semiconductor layer for improved efficiency of a semiconductor structure. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A method for forming a semiconductor structure, the method comprising:
forming a first semiconductor layer, wherein the first semiconductor layer comprises a first semiconductor material; and
forming a second semiconductor layer on the first semiconductor layer, wherein the second semiconductor layer comprises a second semiconductor material, wherein the second semiconductor material is an oppositely-typed semiconductor material from the first semiconductor material, and wherein the second semiconductor layer comprises:
a first region adjacent to the first semiconductor layer, wherein the first region comprises second semiconductor material; and
a second region adjacent to the first region, wherein the second region comprises intentionally-doped second semiconductor material to increase a built-in potential of the semiconductor structure.

2. The method claim 1, wherein forming the second semiconductor layer comprises forming the first region as a low-doped region to maintain depletion width across a majority of an absorption region of the semiconductor structure.

3. The method of claim 1, further comprising forming an ohmic contact on the second semiconductor layer.

4. The method of claim 3, wherein forming the second semiconductor layer comprises doping the second semiconductor material with a first dopant, and wherein forming the ohmic contact comprises forming the ohmic contact using a second dopant.

5. The method of claim 1, wherein forming the second semiconductor layer comprises:
forming the first region on the first semiconductor layer; and
forming the second region on the first region.

6. The method of claim 5, wherein forming the second region comprises:
forming at least one layer of high-doped second semiconductor material.

7. The method of claim 6, wherein forming the second region further comprises:
forming at least one layer of low-doped second semiconductor material.

8. The method of claim 1, wherein forming the second semiconductor layer comprises:
forming an at least one layer of second semiconductor material; and
diffusing an at least one dopant through the an at least one layer of second semiconductor material to form the first region and the second region.

9. The method of claim 1, wherein forming the second semiconductor layer is performed using a method selected from the group consisting of step-doping, graded doping, and modulation doping.

10. The method of claim 1, wherein forming the second semiconductor layer comprises forming a moderately doped second semiconductor layer, wherein the first region comprises moderately doped second semiconductor material and wherein the second region comprises moderately doped second semiconductor material.

11. The method claim 1, wherein forming the second semiconductor layer comprises forming the second region as a highly-doped region to maintain depletion width across a majority of an absorption region of the semiconductor structure.

12. A method for forming a semiconductor structure, the method comprising:
forming a first layer, wherein the first layer comprises a first semiconductor material;
forming a second layer on the first layer, wherein the second layer comprises low-doped second semiconductor material, wherein the second semiconductor material and the first semiconductor material are oppositely-typed semiconductor materials; and
forming a third layer on the second layer, wherein the third layer comprises high-doped second semiconductor material.

13. The method of claim 12, wherein forming the second layer comprises forming an at least one layer of extrinsic second semiconductor material.

14. The method of claim 12, wherein forming the at least one layer of extrinsic semiconductor material comprises:
forming an at least one layer of intrinsic second semiconductor material; and
diffusing dopant through the third layer into the at least one layer of intrinsic second semiconductor material to form the at least one layer of extrinsic semiconductor material.

15. The method of claim 12, wherein forming the third layer comprises forming an at least one layer of degenerate second semiconductor material.

16. The method of claim 12, wherein:
forming the first layer comprises forming a layer of n-type CdS;
forming the second layer comprises forming a layer of p(⁻)-type CdTe; and
forming the third layer comprises forming a layer of p(⁺)-type CdTe.

17. The method of claim 12, wherein forming the third layer comprises:
forming a first film, wherein the first film comprises low-doped semiconductor material;
forming a second film on the first film, wherein the second film comprises high-doped semiconductor material;
forming a third film on the second film, wherein the third film comprises low-doped semiconductor material; and
forming a fourth film on the third film, wherein the fourth film comprises high-doped semiconductor material.

18. The method of claim 12, wherein:
forming the second layer comprises forming a region of p(⁻)-type doped second semiconductor material; and
forming the third layer comprises forming a region of p(⁺)-type doped second semiconductor material

19. The method of claim 12, wherein:
forming the first layer comprises forming a layer of n-type CdS;
forming the second layer comprises forming a layer of p(⁻)-type CIGS; and
forming the third layer comprises forming a layer of p(⁺)-type CIGS.

20. A method for forming a semiconductor structure, the method comprising:
forming a first layer, wherein the first layer comprises a n-type semiconductor material; and
forming a second layer, wherein the second layer comprises a p-type semiconductor material, wherein the second layer is intentionally-doped to increase a built-in potential of the semiconductor structure.
